(19) United States
(12) Patent Application Publication
(10) Pub. No.: US 2016/0276540 A1
(43) Pub. Date: Sep. 22, 2016

(54) SEMICONDUCTOR LIGHT-EMITTING ELEMENT

(71) Applicant: KABUSHIKI KAISHA TOSHIBA, Tokyo (JP)

(72) Inventors: Kazuyuki MIYABE, Kanazawa Ishikawa (JP); Akira ISHIGURO, Kanazawa Ishikawa (JP); Hiroshi KATSUNO, Komatsu Ishikawa (JP); Shinji YAMADA, Nonoichi Ishikawa (JP)

(21) Appl. No.: 15/046,188

(22) Filed: Feb. 17, 2016

(30) Foreign Application Priority Data
Mar. 16, 2015 (JP) 2015-052135

(51) Int. Cl. H01L 33/38; H01L 33/62; H01L 33/20; H01L 33/24; H01L 33/00; H01L 33/22

(52) U.S. Cl. CPC H01L 33/382; H01L 33/0012; H01L 33/22; H01L 33/20; H01L 33/24; H01L 33/62

(57) ABSTRACT

A semiconductor light-emitting element includes a substrate having a convex portion protruding therefrom. A first semiconductor layer having a first conductivity type is separated from the substrate in a first direction. A second semiconductor layer of a second conductivity type is between the first semiconductor layer and the substrate. A third semiconductor is between the first and second semiconductor layers. A first electrode is provided between the first semiconductor layer and the substrate, and is electrically connected to the first semiconductor layer. A second electrode is provided between the second semiconductor layer and the substrate, and is electrically connected to the second semiconductor layer. A metal layer is between the first electrode and the second region, and between the second electrode and the first region. The metal layer includes a concave portion which conforms to the convex portion of the substrate.

### CROSS-REFERENCE TO RELATED APPLICATION

This application is based upon and claims the benefit of priority from Japanese Patent Application No. 2015-052135, filed Mar. 16, 2015, the entire contents of which are incorporated herein by reference.

### FIELD

Embodiments described herein relate generally to a semiconductor light-emitting element.

### BACKGROUND

There is a demand for improvement of productivity in a semiconductor light-emitting element such as light-emitting diode (LED).

### DESCRIPTION OF THE DRAWINGS

FIGS. 1A and 1B are schematic views which illustrate a semiconductor light-emitting element according to a first embodiment.

FIGS. 2A to 2D are schematic cross sectional views depicting a process sequence in a manufacturing of the semiconductor light-emitting element according to the first embodiment.

FIGS. 3A to 3C are schematic cross sectional views depicting a process sequence in the manufacturing of the semiconductor light-emitting element according to the first embodiment.

FIGS. 4A to 4B are schematic cross sectional views depicting a process sequence in the manufacturing of the semiconductor light-emitting element according to the first embodiment.

FIG. 5 is a schematic sectional view which illustrates a semiconductor light-emitting element according to a reference example.

FIG. 6 is a schematic sectional view which illustrates a semiconductor light-emitting element according to a second embodiment.

### DETAILED DESCRIPTION

Embodiments described herein provide a semiconductor light-emitting element with high productivity.

In general, according to embodiments, a semiconductor light-emitting element includes a substrate that includes a first region and a second region having a convex portion protruding from the first region. A first semiconductor layer of a first conductivity type is on the substrate. The substrate and the first semiconductor layer are spaced from each other in the first direction. A second semiconductor layer of a second conductivity type is between the first semiconductor layer and the substrate. A third semiconductor layer is between the first semiconductor layer and the second semiconductor layer. A first electrode is between the first semiconductor layer and the substrate and electrically connected to the first semiconductor layer. A second electrode is between the second semiconductor layer and the substrate and electrically connected to the second semiconductor layer. A metal layer is between the first electrode and the second region, and between the second electrode and the first region. The metal layer includes a concave portion which is fitted to (conforms to) the convex portion of the substrate in the second region.

Hereinafter, example embodiments of the present disclosure will be described with reference to drawings.

The drawings are schematic or conceptual, and are not necessarily drawn to scale.

In the present disclosure, the same elements depicted in different figures are denoted by the same reference numerals, a detailed description of elements previously described in conjunction with an earlier figure may be omitted as appropriate.

### First Embodiment

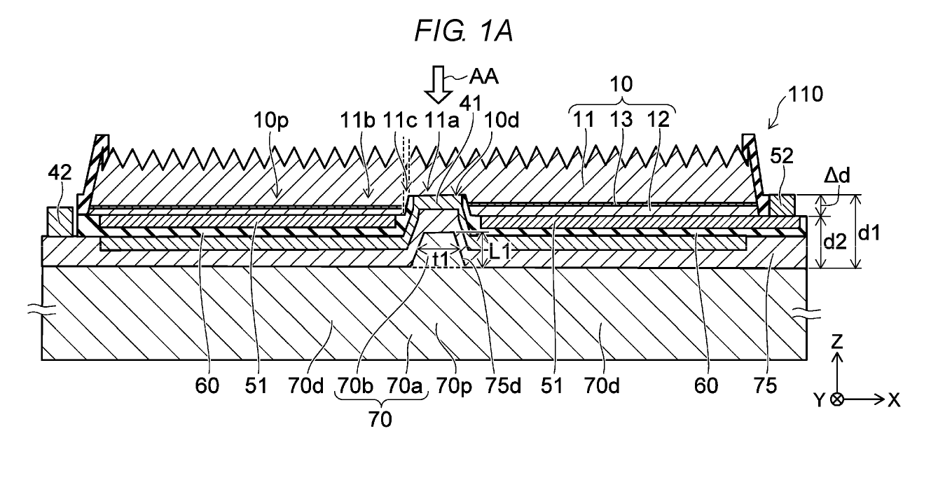

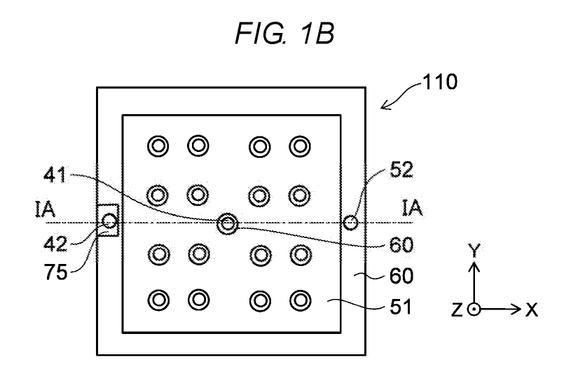

FIGS. 1A and 1B are schematic views which illustrate a semiconductor light-emitting element 110 according to a first embodiment.

FIG. 1A is a sectional view which is taken along line IA-IA of FIG. 1B.

FIG. 1B is a plan view which is viewed from arrow AA of FIG. 1A.

As shown in FIG. 1A, the semiconductor light-emitting element 110 includes a first semiconductor layer 11, a second semiconductor layer 12, a third semiconductor layer 13, a substrate 70, a metal layer 75, an insulating layer 60, a first electrode 41, and a second electrode 51.

As the substrate 70, a semiconductor substrate of silicon (Si) or sapphire is used. The substrate 70 maybe electrically conductive.

The first semiconductor layer 11 is first conductivity type. The first semiconductor layer 11 is separated from the substrate 70 in a first direction.

The first direction may be defined as a Z axis direction. A second direction perpendicular to the Z axis direction may be defined as an X axis direction. A direction perpendicular to the Z axis direction and the X axis direction maybe defined as a Y axis direction.

The first semiconductor layer 11 includes a first semiconductor region 11a and a second semiconductor region 11b which is aligned with the first semiconductor region 11a in the second direction. Furthermore, the first semiconductor layer 11 includes a third semiconductor region 11c between the first semiconductor region 11a and the second semiconductor region 11b.

The second semiconductor layer 12 is a second conductivity type. The second semiconductor layer 12 is provided between the second semiconductor region 11b and the substrate 70. The second semiconductor layer 12 and the first semiconductor layer 11 are stacked in the Z axis direction.

The first conductivity type may be n-type, and the second conductivity type may be p-type, or vice versa. In the following example, the first conductivity type is n-type, and the second conductivity type is p-type.

The third semiconductor layer 13 is provided between the second semiconductor region 11b and the second semiconductor layer 12. The third semiconductor layer 13 may include an active layer. The third semiconductor layer 13 may be a light-emitting portion.

The first semiconductor layer 11, the second semiconductor layer 12, and the third semiconductor layer 13 are included in a stacked body 10. The stacked body 10 extends along an X-Y plane, and the stacking is in the Z axis direction.

The stacked body 10 includes a semiconductor convex-shaped portion 10p having a mesa shape. The semiconductor convex-shaped portion 10p includes a portion of the second semiconductor region 11b, the third semiconductor layer 13, and the second semiconductor layer 12. A semiconductor concave-shaped portion 10d which is aligned with the semiconductor convex-shaped portion 10p in the X axis direction is provided in the stacked body 10. The semiconductor convex-shaped portion 10p and the semiconductor concave-shaped portion 10d may be thought of as steps of the mesa.

The first semiconductor layer 11, the second semiconductor layer 12, and the third semiconductor layer 13 may include a nitride semiconductor. The first semiconductor layer 11 may include, for example, a GaN layer containing n-type impurities. The n-type impurities maybe one or more elements selected from the group consisting of silicon (Si) , oxygen (O), germanium (Ge), tellurium (Te), and tin (Sn). The first semiconductor layer 11 may include, for example, an n-side contact layer. The second semiconductor layer 12 may include, for example, a GaN layer containing p-type impurities. The p-type impurities may be one or more elements selected from the group consisting of magnesium (Mg), zinc (Zn), and cobalt (C). The second semiconductor layer 12 may include a p-side contact layer.

The first electrode 41 is between the substrate 70 and the first semiconductor region 11a. The first electrode 41 is electrically connected to the first semiconductor region 11a and the substrate 70. The first electrode 41 may be an n electrode and may contain aluminum (Al) or an aluminum alloy. The first electrode 41 may be light-reflective. In this example, the first electrode 41 extends between the substrate 70 and the third semiconductor region 11c and between the substrate 70 and the second semiconductor region 11b.

The second electrode 51 is between the substrate 70 and the second semiconductor layer 12 and is electrically connected to the second semiconductor layer 12. The second electrode 51 may be a p electrode and may contain silver (Ag) or a silver alloy. The second electrode 51 may also be light-reflective.

In the present disclosure, two items that are electrically connected may be in direct contact or connected by a third conductor between the two items such that a current flows between the two items. Unless otherwise indicated, the word “overlapped” means overlapping when projected onto the X-Y plane.

The insulating layer 60 is between the substrate 70 and the second electrode 51, and between the first electrode 41 and the second electrode 51. The insulating layer 60 electrically insulates the second electrode 51 from the substrate 70 and the first electrode 41. The insulating layer 60 is between the first electrode 41 and the semiconductor convex-shaped portion 10p along the X axis direction. The insulating layer 60 covers portions of the second electrode 51 and the second semiconductor layer 12. The insulating layer 60 may contain silicon oxide, silicon nitride, and silicon oxynitride.

The metal layer 75 is between the substrate 70 and the first electrode 41, and between the substrate 70 and the second electrode 51. The metal layer 75 may contain tin (Sn), gold (Au), nickel (Ni), an alloy containing tin and gold, and/or an alloy containing tin and nickel. The metal layer 75 is electrically connected to the substrate 70 and the first electrode 41.

The semiconductor light-emitting element 110 includes a first pad 42 and a second pad 52. The first electrode 41, the second electrode 51, the insulating layer 60, and the stacked body 10 are disposed on a portion of the metal layer 75. The first pad 42 is disposed on another portion of the metal layer 75. The first pad 42 is connected to the first electrode 41 and may be an n-side pad. The first pad 42 is electrically connected to the first semiconductor layer 11 through the first electrode 41.

The second pad 52 is disposed on a portion of the second electrode 51 and connected to the second electrode 51. The second pad 52 may be a p-side pad. The second pad 52 is electrically connected to the second semiconductor layer 12 through the second electrode 51.

When a voltage is applied between the first pad 42 and the substrate 70, a current is supplied to the third semiconductor layer 13, and light is emitted from the third semiconductor layer 13. The emitted light is emitted to the outside of the semiconductor light-emitting element 110. The emitted light is reflected by the second electrode 51 and the first electrode 41. A surface (an upper surface in FIG. 1A) of the first semiconductor layer 11 is a light-emitting surface. The semiconductor light-emitting element 110 may be an LED.

In the embodiment of FIG. 1A, the substrate 70 includes a first region 70a and a second region 70b. The second region 70b is between a portion of the first region 70a and the first electrode 41 along the Z axis direction. The second region 70b overlaps the first semiconductor region 11a, and the metal layer 75. The second region 70b is convex and protrudes from the first region 70a in the Z axis direction. A concave portion 75d of the metal layer 75 conforms to the second region 70b.

The substrate 70 includes a convex portion 70p and a concave portion 70d. The convex portion 70p protrudes from the concave portion 70d. The first electrode 41 is disposed on the convex portion 70p. The second electrode 51 is disposed on the concave portion 70d. The second semiconductor layer 12 is disposed on the second electrode 51, and is electrically connected to the second electrode 51. The third semiconductor layer 13 is disposed on the second semiconductor layer 12. The first semiconductor layer 11 is disposed on the first electrode 41 and on the third semiconductor layer 13, and is electrically connected to the first electrode 41.

A material of the substrate 70 is preferably different from a material of the metal layer 75. The substrate 70 may be silicon. The metal layer 75 may be a nickel-tin alloy. Although gold may be used in the metal layer 75, gold is costly.

A thickness t1 of the second region 70b in the Z axis direction may be 0.2 to 0.8 times a first distance d1 from the first semiconductor region 11a to the first region 70a in the Z axis direction. The first distance d1 may be, for example, from 4 micrometers (μm) to 7 μm.

The thickness t1 may be 1.0 to 1.6 times a difference Ad between the first distance d1 and a second distance d2 from the second semiconductor layer 12 to the first region 70a in the Z axis direction. The difference Ad corresponds to a thickness of the semiconductor convex-shaped portion 10p in the Z axis direction. The difference Ad may be between 0.5 pm and 3.5 μm.

A length L1 of the second region 70b in the X axis direction declines in the Z axis direction, so that the side surface of the second region 70b is tapered. The taper may be continuous.

The second region 70b and the first region 70a may be the same material, for example silicon, and the two regions maybe integrally formed by etching or other suitable processes.

The material of the second region 70b may be different from the material of the first region 70a, which may be silicon. The material of the second region 70b may be silicon oxide, silicon nitride, aluminum nitride or the like.

Hereinafter, an example of a method of manufacturing the semiconductor light-emitting element 110 will be described.

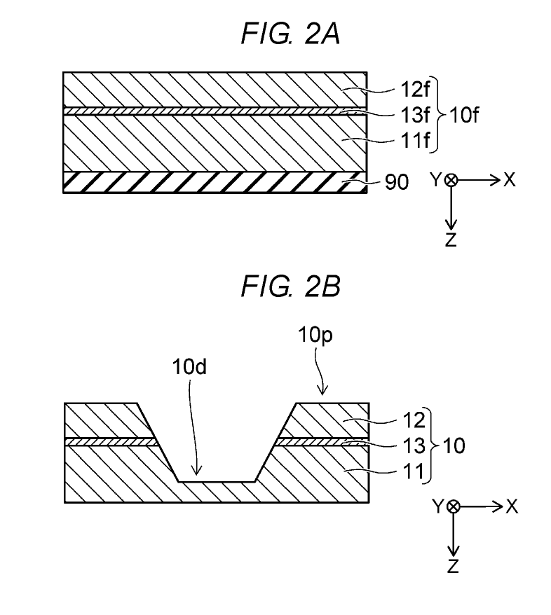

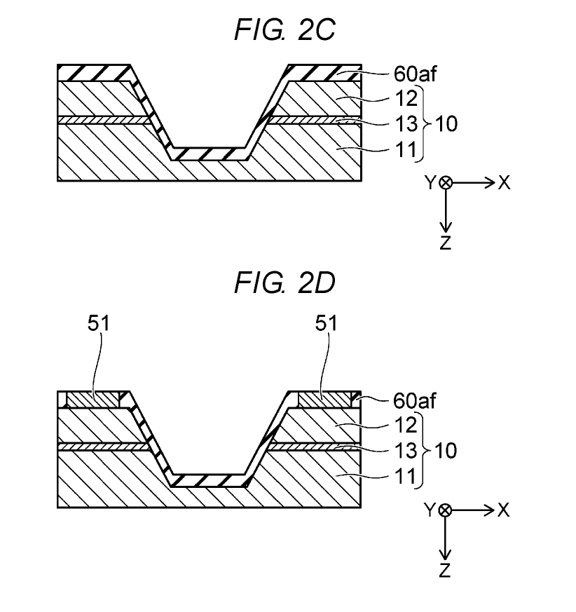

FIGS. 2A to 2D, 3A to 3C, 4A and 4B are schematic sectional views of a process sequence which illustrate the method of manufacturing the semiconductor light-emitting element 110 according to the first embodiment.

As shown in FIG. 2A, a first semiconductor film 11f, corresponding to the first semiconductor layer 11, is formed on a growth substrate 90. A buffer layer (not shown) may be formed between the growth substrate 90 and the first semiconductor film 11f. A third semiconductor film 13f, corresponding to the third semiconductor layer 13, is formed on the first semiconductor film 11f. A second semiconductor film 12f, corresponding to the second semiconductor layer 12, is formed on the third semiconductor film 13f. Accordingly, a stacked film 10f, corresponding to the stacked body 10, is obtained. Metal organic chemical vapor deposition (MOCVD) and the like may be used to form the films 11f, 12f, and 13f. The growth substrate 90 may include any of Si, SiO₂, AlO₂, quartz, sapphire, GaN, SiC, and GaAs.

As shown in FIG. 2B, the stacked body 10 is formed from the stacked body 10f by removing a portion of the second semiconductor film 12f, a portion of the third semiconductor film 13f, and a portion of the first semiconductor film 11f. The growth substrate 90 will be omitted in FIG. 2B and subsequent figures for simplicity. Reactive ion etching (RIE) may be used to remove the portions of the films 11f, 12f, and 13f. In removing the portions of the films, a mesa shape, corresponding to semiconductor convex-shaped portion 10p and semiconductor concave-shaped portion 10,) is formed in the stacked body 10.

As shown in FIG. 2C, a first insulation film 60af is formed on the stacked body 10. The first insulation film 60af may contain silicon oxide, and may be formed by chemical vapor deposition (CVD), sputtering, or by a spin on glass (SOG) method, or other suitable process.

As shown in FIG. 2D, a portion of the first insulation film 60af is removed, and the second electrode 51 is formed on the second semiconductor layer 12 exposed by the removal.

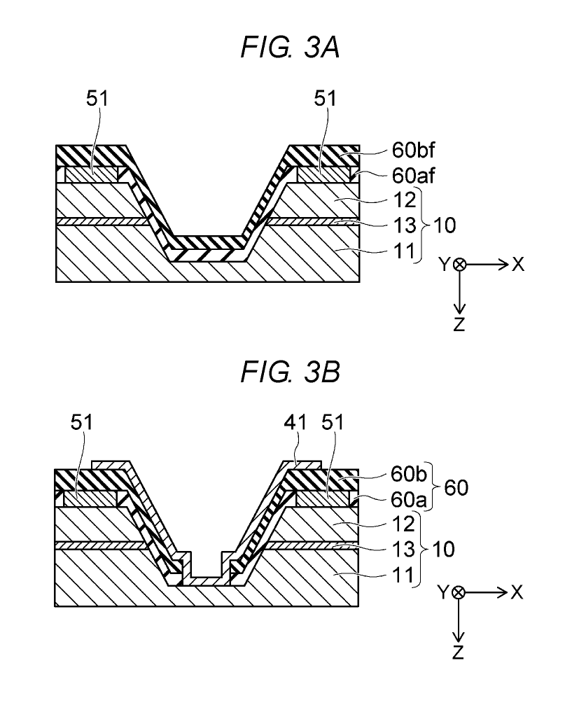

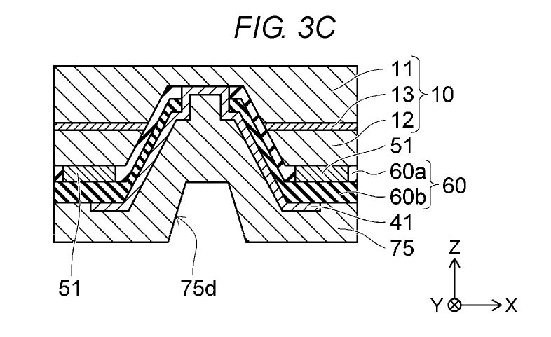

As shown in FIG. 3A, a second insulation film 60bf is formed on the first insulation film 60af and the second electrode 51. The second insulation film 60bf may contain silicon oxide.

As shown in FIG. 3B, the first insulating layer 60a and the second insulating layer 60b are formed by removing a portion of each of the first insulation film 60af and the second insulation film 60bf, respectively. The first electrode 41 is formed on a portion of first semiconductor layer 11 exposed by these removals. The first insulating layer 60a and the second insulating layer 60b constitute the insulating layer 60.

As shown in FIG. 3C, the metal layer 75 is formed on the first electrode 41 and the insulating layer 60. The metal layer concave portion 75d which conforms to the second region 70b of the substrate 70 is formed in the metal layer 75, in a step portion of the mesa, by sputtering or vapor deposition.

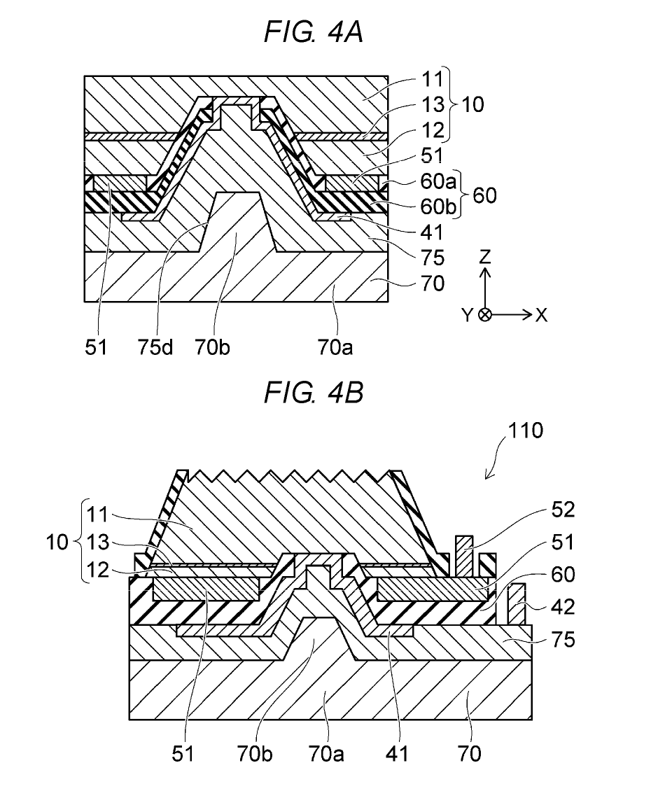

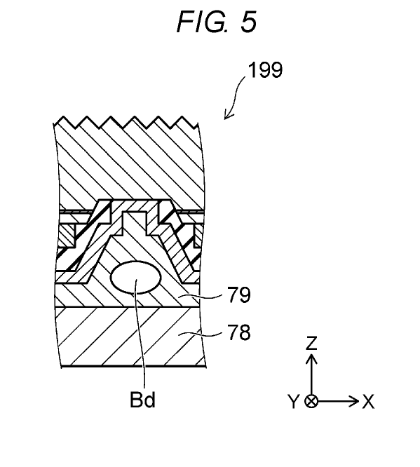

As shown in FIG. 4A, the substrate 70 is formed on the metal layer 75. The substrate 70 includes the first region 70a and the second region 70b, and the second region 70b conforms to the metal layer concave portion 75d. If desired, the position of the metal layer concave portion 75d may be marked on the second region 70b for reference.

The growth substrate 90 (not shown) may then be removed by grinding, dry etching (for example, RIE), laser lift off (LLO), or the like.

As shown in FIG. 4B, the first pad 42 is formed on a portion of the exposed metal layer 75 after removing a portion of the stacked body 10 and the insulating layer 60. The first pad 42 is then electrically connected to the first electrode 41. The second pad 52 is formed on the exposed second electrode 51 after removing another portion of the stacked body 10. The second pad 52 is then electrically connected to the second electrode 51. Unevenness may be formed on an upper surface of the first semiconductor layer 11. A protective film, which may be an insulating layer, may be formed on a side surface of the stacked body 10. The substrate 70 may be thinned to any desired dimension. In the manufacturing process described above, sequences of processing may be changed in a technically allowed range. Annealing processing may be appropriately performed.

Accordingly, the semiconductor light-emitting element 110 is obtained.

As described above, the substrate 70 includes the first region 70a and the second region 70b in the semiconductor light-emitting element 110. The second region 70b is provided between the first region 70a and the first electrode 41 along the Z axis direction. For example, the second region 70b overlaps the first semiconductor region 11a and the metal layer 75. The manufacturing process described above increases productivity in manufacturing semiconductor light-emitting elements by minimizing the opportunity for voids to be formed.

FIG. 5 is a schematic sectional view which illustrates a semiconductor light-emitting element 199 according to a reference example susceptible to formation of voids.

A semiconductor light-emitting element 199 according to the reference example has a step portion of a mesa structure. A bonded surface of a metal layer 79 to a substrate 78 is a plane. A bonded surface of the substrate 78 to the metal layer 79 is also a plane. When bonding the substrate 78 and the metal layer 79, a gap occurs. The gap generates a void Bd in the metal layer 79. An occurrence of the void Bd generates bonding peeling and the like in the metal layer 79 to decrease yield and productivity.

Furthermore, when bonding the substrate 78 and the metal layer 79, for example, excessive pressure is typically applied to suppress void formation, and thus stress is concentrated in the step portion of the mesa, thereby applying large stress to the stacked body.

In contrast, in the embodiments described herein, the second region 70b of the substrate 70 is provided between the first region 70a and the first electrode 41 along the Z axis direction. For example, the second region 70b overlaps the first semiconductor region 11a and the metal layer 75. The second region 70b is convex with respect to the first region 70a, and protrudes toward the metal layer 75. The metal layer concave portion 75d conforms to the second region 70b is provided in the metal layer 75. Accordingly, when bonding the substrate 70 and the metal layer 75, it is possible to suppress occurrence of gaps or voids in the metal layer 75, thus increasing yield and productivity, and minimizing the opportunity for peeling.

Moreover, it is possible to reduce stress on the step portion of the mesa by providing the second region 70b of a convex shape in the substrate 70. Accordingly, it is possible to relax stress on the stacked body 10.

### Second Embodiment

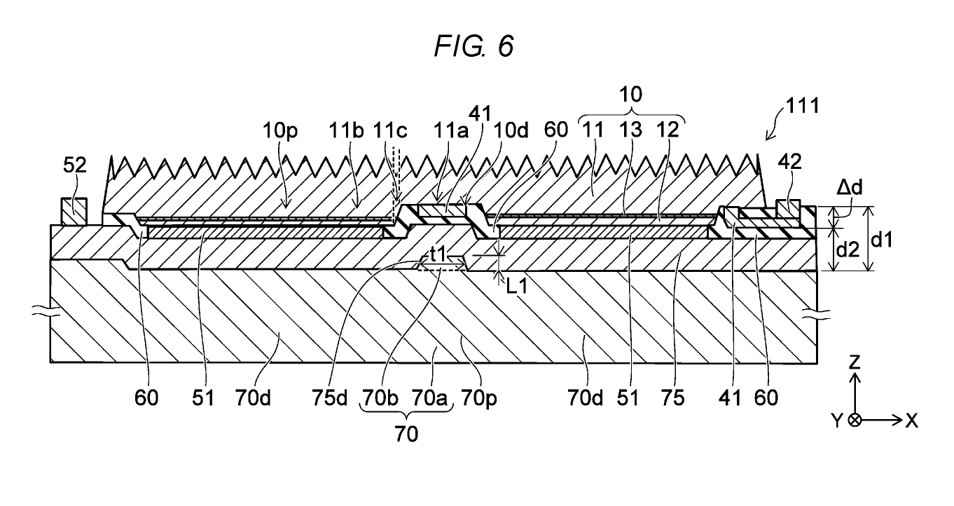

FIG. 6 is a schematic sectional view which illustrates a semiconductor light-emitting element 111 according to a second embodiment.

As shown in FIG. 6, a semiconductor light-emitting element 111 includes the first semiconductor layer 11, the second semiconductor layer 12, the third semiconductor layer 13, the substrate 70, the metal layer 75, the insulating layer 60, the first electrode 41, and the second electrode 51.

The substrate 70 includes the first region 70a and the second region 70b. The second region 70b is between a portion of the first region 70a and the first electrode 41 along the Z axis direction. The second region 70b overlaps the first semiconductor region 11a and the metal layer 75. The second region 70b is convex and protrudes toward the metal layer 75. The metal layer concave portion 75d conforms to the second region 70b.

Thus, the substrate 70 includes the convex portion 70p and the concave portion 70d. The first electrode 41 is disposed on the concave portion 70d. The second electrode 51 is disposed on the convex portion 70p. The second semiconductor layer 12 is disposed on the second electrode 51, and is electrically connected to the second electrode 51. The third semiconductor layer 13 is disposed on the second semiconductor layer 12. The first semiconductor layer 11 is disposed on the first electrode 41 and on the third semiconductor layer 13, and is electrically connected to the first electrode 41.

The metal layer 75 is between the first electrode 41 and the second region 70b, and between the second electrode 51 and the first region 70a. The metal layer 75 may contain tin (Sn), gold (Au), nickel (Ni), an alloy containing tin and gold, and/or an alloy containing tin and nickel. The metal layer 75 is electrically connected to the substrate 70 and the second electrode 51.

The insulating layer 60 is between the substrate 70 and the first electrode 41, and between the first electrode 41 and the second electrode 51. The insulating layer 60 electrically insulates the first electrode 41 from the substrate 70 and the second electrode 51. The insulating layer 60 is between the first electrode 41 and the semiconductor convex-shaped portion 10p along the X axis direction. The insulating layer 60 covers a portion of the first electrode 41 and the first semiconductor region 11a. The insulating layer 60 may contain silicon oxide, silicon nitride, silicon oxynitride, and the like.

The semiconductor light-emitting element 111 includes the first pad 42 and the second pad 52. The first electrode 41, the second electrode 51, the insulating layer 60, and the stacked body 10 are disposed on a portion of the metal layer 75. The second pad 52 is disposed on another portion of the metal layer 75, and is connected to the second electrode 51. The second pad 52 may be a p-side pad. The second pad 52 is electrically connected to the second semiconductor layer 12 through the second electrode 51.

The first pad 42 is disposed on a portion of the first electrode 41. The first pad 42 is connected to the first electrode 41, and may be an n-side pad. The first pad 42 is electrically connected to the first semiconductor layer 11 through the first electrode 41.

The material of the substrate 70 is preferably different from the material of the metal layer 75. Silicon may be used for the substrate 70. A nickel-tin alloy may be used for the metal layer 75. Gold may be used in the metal layer 75, but gold is relatively costly.

The thickness t1 of the second region 70b in the Z axis direction may be 0.2 to 0.8 times a first distance dl from the first semiconductor region 11a to the first region 70a in the X axis direction. The first distance dl may be 4 μm to 7 μm.

The thickness t1 may be 1.0 to 1.6 times a difference Ad between the first distance d1 and the second distance d2 from the second semiconductor layer 12 to the first region 70a in the Z axis direction. The difference Ad corresponds to a thickness of the semiconductor convex-shaped portion 10p in the Z axis direction. The difference Ad may be 0.5 μm to 3.5 μm.

The length L1 of the second region 70b in the X axis direction declines in the Z axis direction, so that a side surface of the second region 70b is tapered. The change in length L1 may be continuous.

The first region 70a and the second region 70b may be the same material, for example silicon, and may be integrally formed by etching or other suitable processes.

The first region 70a and the second region 70b may be different materials. The first region 70a maybe silicon, and the second region 70b may be silicon oxide, silicon nitride, aluminum nitride, and the like.

According to the embodiment, it is possible to provide a semiconductor light-emitting element with high productivity.

As described above, embodiments of the present disclosure are described with reference to specific examples. However, the present disclosure is not limited to these specific examples.

In addition, a combination of elements from specific examples may be combined when technically feasible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor light-emitting element, comprising:
a substrate that includes a first region and a second region having a convex portion protruding from the first region;
a first semiconductor layer of a first conductivity type on the substrate, the substrate and the first semiconductor layer being spaced from each other in a first direction;
a second semiconductor layer of a second conductivity type between the first semiconductor layer and the substrate;
a third semiconductor layer between the first semiconductor layer and the second semiconductor layer;
a first electrode between the first semiconductor layer and the substrate and electrically connected to the first semiconductor layer; and
a second electrode between the second semiconductor layer and the substrate and electrically connected to the second semiconductor layer; and
a metal layer between the first electrode and the second region, and between the second electrode and the first region,
wherein the metal layer includes a concave portion which conforms to the convex portion.

2. The semiconductor light-emitting element according to claim 1, wherein the first semiconductor layer and the first electrode are electrically connected to each other above the second region in the first direction.

3. The semiconductor light-emitting element according to claim 2, wherein a material of the substrate is different from a material of the metal layer.

4. The semiconductor light-emitting element according to claim 1, wherein a thickness of the second region in the first direction is 0.2 to 0.8 times a first distance between the first semiconductor layer and the first region in the first direction.

5. The semiconductor light-emitting element according to claim 4, wherein the first distance is in a range of 4 micrometers to 7 micrometers.

6. The semiconductor light-emitting element according to claim 1, wherein a thickness of the second region in the first direction is 1.0 to 1.6 times a difference between a first distance along the first direction from the first semiconductor layer to the substrate in the first region and a second distance along the first direction from the second semiconductor layer to the substrate in the first region.

7. The semiconductor light-emitting element according to claim 6, wherein the difference is in a range of 0.5 micrometers to 3.5 micrometers.

8. The semiconductor light-emitting element according to claim 1, wherein a length of the second region in a second direction intersecting with the first direction decreases with increasing distance along a direction from the substrate towards the first electrode.

9. The semiconductor light-emitting element according to claim 1, wherein a material in the second region is different from a material in the first region.

10. The semiconductor light-emitting element according to claim 2, wherein the metal layer is electrically connected to the first electrode.

11. The semiconductor light-emitting element according to claim 10, further comprising:
an insulating layer between the second electrode and the metal layer, and between the first electrode and the second electrode.

12. The semiconductor light-emitting element according to claim 2, wherein the metal layer is electrically connected to the second electrode.

13. The semiconductor light-emitting element according to claim 12, further comprising:
an insulating layer between the first electrode and the metal layer, and between the first electrode and the second electrode.

14. A semiconductor light-emitting element, comprising:
a substrate;
a first semiconductor layer of a first conductivity type that is separated from the substrate in a first direction and includes a first semiconductor region and a second semiconductor region that is aligned with the first semiconductor region in a second direction intersecting with the first direction;
a second semiconductor layer of a second conductivity type between the second semiconductor region and the substrate;
a third semiconductor layer between the second semiconductor region and the second semiconductor layer;
a first electrode between the first semiconductor region and the substrate and electrically connected to the first semiconductor region, wherein the substrate includes a first region and a second region between a portion of the first region and the first electrode;
a second electrode between the second semiconductor layer and the substrate and electrically connected to the second semiconductor layer; and
a metal layer between the first electrode and the second region, and between the second electrode and the first region.

15. The semiconductor light-emitting element of claim 14, wherein the second region overlaps the first semiconductor region in the first direction, and overlaps the metal layer in the second direction.

16. The semiconductor light-emitting element of claim 14, wherein the metal layer is electrically connected to the first electrode.

17. The semiconductor light-emitting element of claim 16, further comprising an insulating layer between the second electrode and the metal layer, and between the first electrode and the second electrode.

18. The semiconductor light-emitting element of claim 14, wherein the metal layer is electrically connected to the second electrode.

19. The semiconductor light-emitting element of claim 14, wherein a length of the second region in the second direction decreases from the substrate towards the first electrode.

20. A semiconductor light-emitting element, comprising:
a substrate;
a first semiconductor layer of a first conductivity type on the substrate, the substrate and the first semiconductor layer being spaced from each other in a first direction, the first semiconductor layer including a first semiconductor region and a second semiconductor region that is aligned with the first semiconductor region in a second direction intersecting the first direction;
a second semiconductor layer of a second conductivity type between the second semiconductor region and the substrate;
a third semiconductor layer between the second semiconductor region and the second semiconductor layer;
a first electrode between the first semiconductor region and the substrate and electrically connected to the first semiconductor region, wherein the substrate includes a first region and a second region between a portion of the first region and the first electrode;
a second electrode between the second semiconductor layer and the substrate and electrically connected to the second semiconductor layer; and
a metal layer between the first electrode and the second region, and between the second electrode and the first region,
wherein a length of the second region in the second direction decreases from the substrate towards the first electrode.
